(19) United States
(12) Patent Application Publication
(10) Pub. No.: US 2020/0312798 A1
(43) Pub. Date: Oct. 1, 2020

(54) ANTENNA APPARATUS, ANTENNA MODULE, AND WIRELESS APPARATUS

(71) Applicant: Murata Manufacturing Co., Ltd., Kyoto (JP)

(72) Inventor: Kazunari KAWAHATA, Kyoto (JP)

(21) Appl. No.: 16/899,873

(22) Filed: Jun. 12, 2020

Related U.S. Application Data
(63) Continuation of application No. PCT/JP2018/044369, filed on Dec. 3, 2018.

(30) Foreign Application Priority Data
Dec. 14, 2017 (JP) 2017-239239

(51) Int. Cl. H01L 23/66; H01Q 1/48; H01Q 9/04; G01S 7/03

(52) U.S. Cl. CPC H01L 23/66; H01Q 1/48; H01L 2223/6627; G01S 7/032; H01L 2223/6677; H01Q 9/0407

(57) ABSTRACT

A feeding element is disposed on or in a first substrate. A second substrate overlies the feeding element. The second substrate is a flexible substrate including an extending portion extending outside the first substrate. A parasitic element coupled to the feeding element is disposed on or in the second substrate. A radiating electrode connected to the parasitic element is disposed on the extending portion of the second substrate.

This is a continuation of International Application No. PCT/JP2018/044369 filed on Dec. 3, 2018 which claims priority from Japanese Patent Application No. 2017-239239 filed on Dec. 14, 2017. The contents of these applications are incorporated herein by reference in their entireties.

### BACKGROUND

### Technical Field

The present disclosure relates to an antenna apparatus, antenna module, and wireless apparatus.

There is a publicly known antenna system in which an RFIC is mounted on a hybrid laminate module substrate and a radiating element is formed on one surface (Patent Document 1). In that antenna system, a substrate made of FR-4 is fixed on one surface of the flexible substrate in a die region, and the RFIC and the like are mounted on the other surface. The flexible substrate extends to outside the substrate made of FR-4, and the radiating element of the antenna is arranged on that extending portion.

There is a publicly known wireless device including antenna elements on a plurality of surfaces pointing in different directions (Patent Document 2). With that configuration, the LOS coverage can be improved. In one example, an array antenna is arranged on each of the front and upper surfaces of the wireless device.
Patent Document 1: U.S. Patent Application Publication No. 2012/0235881
Patent Document 2: International Publication No. 2013/033650

### BRIEF SUMMARY

In the antenna system disclosed in Patent Document 1, no radiating element is arranged on a rigid portion composed of FR-4 and the like. The size of an effective aperture portion of the antenna is restricted by the size of the extending portion of the flexible substrate. In the wireless device disclosed in Patent Document 2, each of the array antennas on the plurality of surfaces is needed to be connected to a feeding line from an RFIC. Therefore, it is difficult to configure the RFIC and the array antennas on the plurality of surfaces as a single module.

The present disclosure provides an antenna apparatus suited for widening its angle and being modularized and capable of having an enlarged effective aperture portion of the antenna. The present disclosure provides an antenna module and a wireless apparatus using that antenna apparatus.

According to an aspect of the present disclosure, provided is an antenna apparatus including

a feeding element disposed on or in a first substrate,

a second substrate that is flexible, that overlies the feeding element, and that includes an extending portion extending outside the first substrate,

a parasitic element disposed on or in the second substrate and coupled to the feeding element, and

a radiating electrode disposed on the extending portion of the second substrate and connected to the parasitic element.

According to another aspect of the present disclosure, provided is an antenna module including

a feeding element disposed on or in a first substrate,

a second substrate that is flexible, that overlies the feeding element, and that includes an extending portion extending outside the first substrate,

a parasitic element disposed on or in the second substrate and coupled to the feeding element,

a radiating electrode disposed on the extending portion of the second substrate and connected to the parasitic element,

a transmission and reception circuit element disposed on or in the first substrate and configured to supply a high-frequency signal to the feeding element, and

a signal line disposed on or in the second substrate, allowing at least one of an intermediate-frequency signal, a local signal, and a direct-current power to be supplied to the transmission and reception circuit element, and extending to the extending portion.

According to still another aspect of the present disclosure, provided is a wireless apparatus including

a feeding element disposed on or in a first substrate,

a second substrate that is flexible, that overlies the feeding element, and that includes an extending portion extending outside the first substrate,

a parasitic element disposed on or in the second substrate and coupled to the feeding element,

a radiating electrode disposed on the extending portion of the second substrate and connected to the parasitic element,

a transmission and reception circuit element disposed on or in the first substrate and configured to supply a high-frequency signal to the feeding element,

a signal line disposed on or in the second substrate, connected to the transmission and reception circuit element, and extending to the extending portion, and

a baseband integrated circuit configured to supply at least one of an intermediate-frequency signal, a local signal, and a direct-current power to the transmission and reception circuit element through the signal line and configured to perform a baseband signal.

Because the feeding element and the parasitic element are arranged in the region overlapping the first substrate and the radiating electrode is arranged on the extending portion, the effective aperture portion of the antenna can be enlarged. Bending the second substrate can provide a wide angle. Mounting the transmission and reception circuit element for high frequencies on the first substrate can enable easily configuring the antenna module including the transmission and reception circuit element.

### BRIEF DESCRIPTION OF THE SEVERAL VIEWS OF THE DRAWINGS

FIG. 1A is a schematic perspective view of an antenna apparatus according to a first embodiment, FIG. 1B is a cross-sectional view taken along a dash-dotted line 1B-1B in FIG. 1A, and FIG. 1C is a cross-sectional view of a state in which a second substrate is bent.

FIGS. 2A, 2B, and 2C are plan views each illustrating an antenna apparatus according to a variation of the first embodiment.

FIGS. 3A and 3B are cross-sectional views each illustrating an antenna apparatus according to a variation of the first embodiment.

FIG. 4A is a plan view of an antenna module according to a second embodiment, and FIG. 4B is a cross-sectional view taken along a dash-dotted line 4B-4B in FIG. 4A.

FIGS. 5A and 5B are plan views that illustrate a relative positional relationship of a first substrate and a second substrate of an antenna apparatus according to a third embodiment and that according to a variation of the third embodiment, respectively.

FIG. 6A is a block diagram of a wireless apparatus according to a fourth embodiment, and FIG. 6B is a block diagram of an in-vehicle radar according to a fifth embodiment.

### DETAILED DESCRIPTION

### First Embodiment

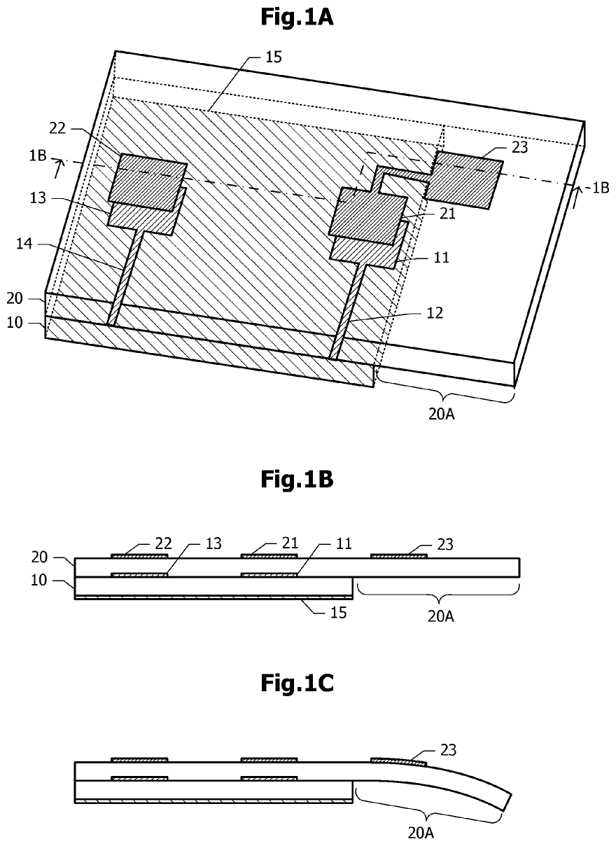

An antenna apparatus according to a first embodiment is described with reference to FIGS. 1A, 1B, and 1C.

FIG. 1A is a schematic perspective view of the antenna apparatus according to the first embodiment. FIG. 1B is a cross-sectional view taken along a dash-dotted line 1B-1B in FIG. 1A. Feeding elements (terminals) 11 and 13 are disposed on an upper surface of a first substrate 10. High-frequency signals are supplied to the feeding elements 11 and 13 through feeding lines 12 and 14, respectively. A ground plane 15 is disposed on a lower surface of the first substrate 10.

The feeding elements 11 and 13 are overlaid with a second substrate 20. The second substrate 20 is fixed to the upper surface of the first substrate 10. The second substrate 20 includes an extending portion 20A extending outside the first substrate 10 as seen in plan view. Parasitic elements 21 and 22 and a radiating electrode 23 are disposed on an upper surface of the second substrate 20 (surface opposite to the surface facing the first substrate 10). Examples of the two-dimensional shape of each of the feeding elements 11 and 13, parasitic elements 21 and 22, and radiating electrode 23 may include a square and a rectangle. Examples of that two-dimensional shape may further include other shapes, such as a circle or an ellipse.

The parasitic elements 21 and 22 are stacked above the feeding elements 11 and 13, respectively, with a gap interposed therebetween and are coupled to the feeding elements 11 and 13, respectively. Secondary resonance occurs in the feeding element 11 and the parasitic element 21, and secondary resonance occurs in the feeding element 13 and the parasitic element 22. The feeding elements 11 and 13, parasitic elements 21 and 22, and ground plane 15 constitute two stacked patch antennas. The radiating electrode 23 is arranged on the extending portion 20A and is connected to the parasitic element 21.

As the first substrate 10, a rigid substrate is used, and as the second substrate 20, a flexible substrate is used. Thus, the extending portion 20A of the second substrate 20 is easily bendable. The first substrate 10 has mechanical bearing power and bears the second substrate 20. A transmission and reception circuit element and the like can also be disposed on or in the first substrate 10.

Next, great advantages obtainable from the adoption of the configuration of the antenna apparatus according to the first embodiment are described.

When a high-frequency signal is supplied to the feeding element 11, the parasitic element 21, which is coupled thereto, is also excited, and a high-frequency current flows through the parasitic element 21. The high-frequency current flowing through the parasitic element 21 partially leaks to the radiating electrode 23, which is connected to the parasitic element 21, and the radiating electrode 23 is excited. Because the radiating electrode 23, which is arranged outside the first substrate 10 as seen in plan view, is also excited, the size of the effective aperture portion of the antenna can be increased without necessarily enlarging the first substrate 10. The antenna design of the radiating electrode 23 can provide a wider angle and higher gain.

Because secondary resonance occurs between the feeding element 11 and the parasitic element 21 and between the feeding element 13 and the parasitic element 22, the operating frequency band can be broadened.

Because the radiating electrode 23 is arranged on the extending portion 20A of the second substrate 20, the directivity can be easily changed by adjustment of the attitude of the radiating electrode 23 by bending the extending portion 20A, as illustrated in FIG. 1C. Thus, a wide angle as the antenna apparatus can be achieved.

Because the radiating electrode 23 and the parasitic element 21 are disposed on the same surface of the second substrate 20, the radiating electrode 23 can be coupled to the parasitic element 21 without necessarily a via interposed therebetween. Thus, transmission loss arising from the via can be avoided.

When the first substrate 10, feeding elements 11 and 13, and ground plane 15 are commonized to a plurality of product categories, the cost can be reduced. In that case, when the second substrates 20 designed for antennas corresponding to the product categories are prepared and are bonded to the common first substrates 10, the antenna apparatus for each of the product categories can be achieved.

### Variations of First Embodiment

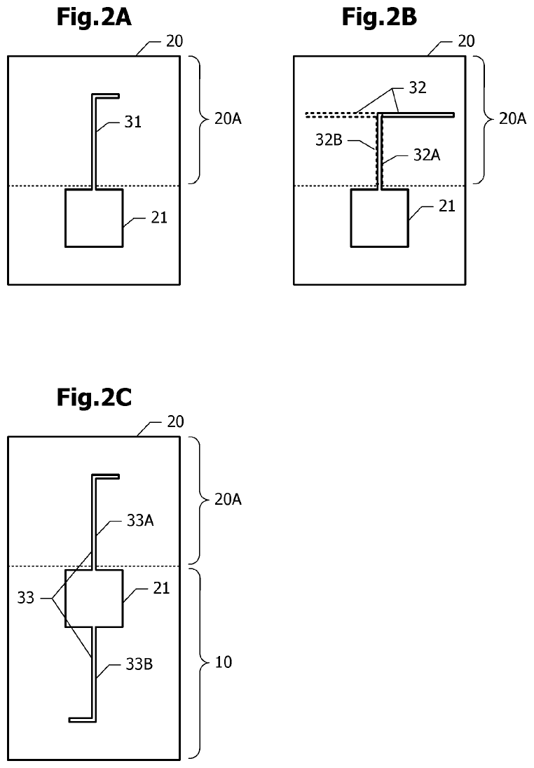

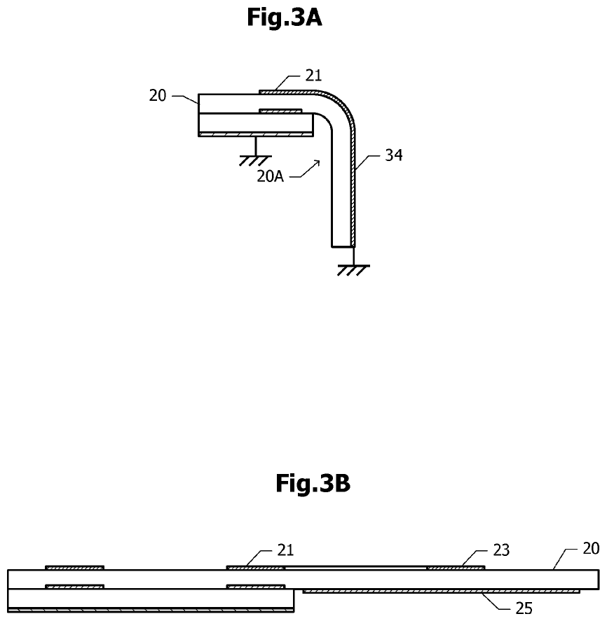

Next, antenna apparatuses according to variations of the first embodiment are described with reference to FIGS. 2A to 3B. In the first embodiment, a conductive pattern having a square or rectangular two-dimensional shape is used as one example of the radiating electrode 23. In variations described below, in place of the square or rectangular radiating electrode 23, radiating electrodes having various shapes are used. FIGS. 2A to 2C are plan views of antenna apparatuses according to variations of the first embodiment. FIGS. 3A and 3B are cross-sectional views of antenna apparatuses according to variations of the first embodiment.

In the variation illustrated in FIG. 2A, a conducting wire 31 extends from the parasitic element 21 onto the extending portion 20A of the second substrate 20. The conducting wire 31 acts as a monopole antenna.

In the variation illustrated in FIG. 2B, a L-shaped conducting wire 32A extends from the parasitic element 21 onto the extending portion 20A of the second substrate 20. Another L-shaped conducting wire 32B is arranged on the lower surface of the second substrate 20. One linear section of the conducting wire 32B on the lower surface overlaps a linear section of the conducting wire 32A continuous with the parasitic element 21 on the upper surface. In that overlapping portion, the conducting wire 32A and the conducting wire 32B are coupled to each other. The other linear section of the conducting wire 32B on the lower surface and the other linear section of the conducting wire 32A on the upper surface extend in opposite directions as seen in plan view (viewed in a direction perpendicular to the upper surface of the second substrate 20), and they act as a dipole antenna 32.

In the variation illustrated in FIG. 2C, a single conducting wire 33A extends from the parasitic element 21 onto the extending portion 20A of the second substrate 20. Another single conducting wire 33B extends from the parasitic element 21 in a direction opposite to the direction in which the conducting wire 33A extends. The conducting wire 33B is arranged in a region overlapping the first substrate 10. The conducting wires 33A and 33B constitute a dipole antenna 33.

In the variation illustrated in FIG. 3A, a single conducting wire 34 extends from the parasitic element 21 onto the extending portion 20A of the second substrate 20. The extending portion 20A is bent, and the conducting wire 34 is also bent along the shape of the extending portion 20A. The end of the conducting wire 34 is grounded, and the conducting wire 34 acts as a loop antenna.

In the variation illustrated in FIG. 3B, a conductive pattern formed on the upper surface of the second substrate 20 includes the parasitic element 21 and the radiating electrode 23, as in the case of the antenna apparatus according to the first embodiment. In the first embodiment, no ground plane corresponding to the radiating electrode 23 is arranged. In the present variation, a ground plane 25 is disposed on the lower surface of the second substrate 20. The radiating electrode 23 and the ground plane 25 constitute a patch antenna. The ground plane 25 may not be formed on the lower surface of the second substrate 20. The ground plane 25 may be arranged on a layer different from the layer on which the radiating electrode 23 is formed with respect to the thickness direction (a direction perpendicular to an extending direction of the second substrate 20) of the second substrate 20. The directivity direction of the patch antenna can be changed by bending the second substrate 20.

As in the variations illustrated in the drawings of FIGS. 2A to 3B, radiating electrodes for various types of antennas can be used as the radiating electrode formed on the upper surface of the second substrate 20 and connected to the parasitic element 21.

### Second Embodiment

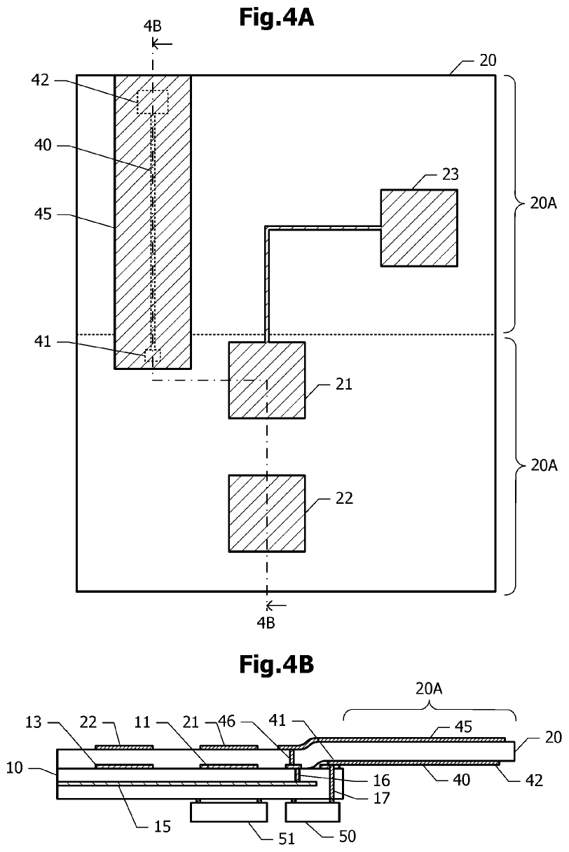

Next, an antenna module according to a second embodiment is described with reference to FIGS. 4A and 4B. In the following description, the same configuration as that in the antenna apparatus according to the first embodiment (FIGS. 1A, 1B, and 1C) is not described.

FIG. 4A is a plan view of the antenna module according to the second embodiment. FIG. 4B is a cross-sectional view taken along a dash-dotted line 4B-4B in FIG. 4A. A signal line 40 is disposed on the lower surface of the second substrate 20. The signal line 40 extends from the region overlapping the first substrate 10 onto the extending portion 20A. A land 41 is disposed on an end portion of the signal line 40 adjacent to the first substrate 10. A connector 42 for connecting the antenna module to an outside circuit, such as a baseband module, is disposed on an end portion of the signal line 40 onto the extending portion 20A. As the connector 42, a connector for use in mounting on a substrate or the like may be used. As the connector 42, a connector for a coaxial cable may also be used.

In addition to the parasitic elements 21 and 22 and radiating electrode 23, a ground plane 45 is disposed on the upper surface of the second substrate 20. The signal line 40 and the ground plane 45 constitute a microstrip line.

The feeding elements 11 and 13 are arranged on the upper surface of the first substrate 10, and the ground plane 15 is arranged on an inner layer. As in the case of the antenna apparatus according to the first embodiment, the ground plane 15, feeding elements 11 and 13, and parasitic elements 21 and 22 constitute stacked patch antennas.

The ground plane 45 disposed on the upper surface of the second substrate 20 is connected to the ground plane 15 with a via 46 disposed through the second substrate 20 and a via 16 disposed through the first substrate 10 interposed therebetween.

A diplexer 50 and a transmission and reception circuit element 51 for high-frequency signals are disposed on the lower surface of the first substrate 10. The signal line 40 is connected to a signal terminal of the diplexer 50 with a via 17 disposed through the first substrate 10 interposed therebetween. An intermediate-frequency signal, a local signal, and direct-current power are superimposed and supplied to the diplexer 50 through the signal line 40. The diplexer 50 separates those superimposed signals in the signal line 40 and supplies them to the transmission and reception circuit element 51. The transmission and reception circuit element 51 performs transmission and reception processing on high-frequency signals for the feeding elements 11 and 13. The intermediate frequency signal, local signal, and direct-current power may not be superimposed, and three signal lines dedicated to transmission of those signals may be arranged.

Next, great advantages obtainable from the adoption of the configuration of the antenna module according to the second embodiment are described. Because the connector 42 for connecting the antenna module to an outside circuit, such as a baseband module, is disposed on the bendable extending portion 20A, the degree of flexibility in arrangement for connecting the antenna module to the outside circuit is enhanced. No cable for connecting the antenna module to the outside circuit is needed, and the number of components can be reduced.

### Third Embodiment

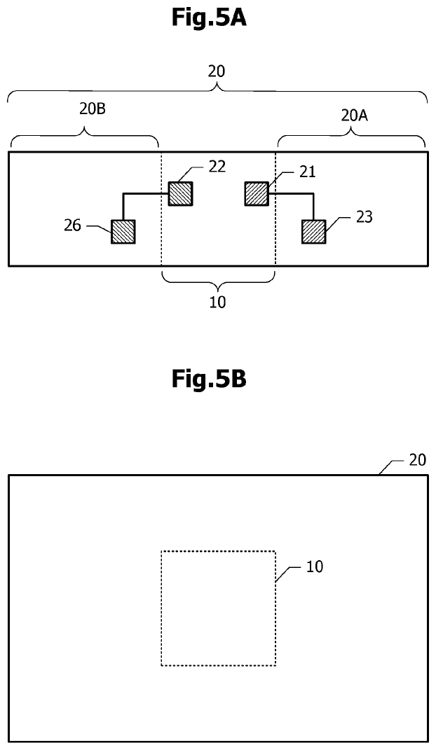

Next, an antenna apparatus according to a third embodiment is described with reference to FIGS. 5A and 5B. In the following description, the same configuration as that in the first embodiment illustrated in FIGS. 1A, 1B, and 1C is not described.

FIG. 5A is a plan view that illustrates a relative positional relationship between the first substrate 10 and the second substrate 20 in the antenna apparatus according to the third embodiment. In the first embodiment, the second substrate 20 extends in one direction with respect to the first substrate 10 (FIG. 1A) as seen in plan view. In the third embodiment, the second substrate 20 extends in two directions (right and left directions in FIG. 5A) with respect to the first substrate 10. Thus, the second substrate 20 includes, in addition to the extending portion 20A, an extending portion 20B.

The radiating electrode 23 connected to the parasitic element 21 is arranged on the extending portion 20A on the one side, as in the case of the first embodiment. A radiating electrode 26 connected to the parasitic element 22 is arranged on the extending portion 20B on the other side.

Next, great advantages obtainable from the adoption of the configuration of the antenna apparatus according to the third embodiment are described. In the third embodiment, the attitudes of the radiating electrodes 23 and 26 can be independently adjusted by bending both the extending portions 20A and 20B. Thus, the degree of flexibility in antenna design for achieving desired directivity characteristics is enhanced.

As illustrated in FIG. 5B, the second substrate 20 may extend in all directions with respect to the first substrate 10. In that case, the degree of flexibility in antenna design is further enhanced.

### Fourth Embodiment

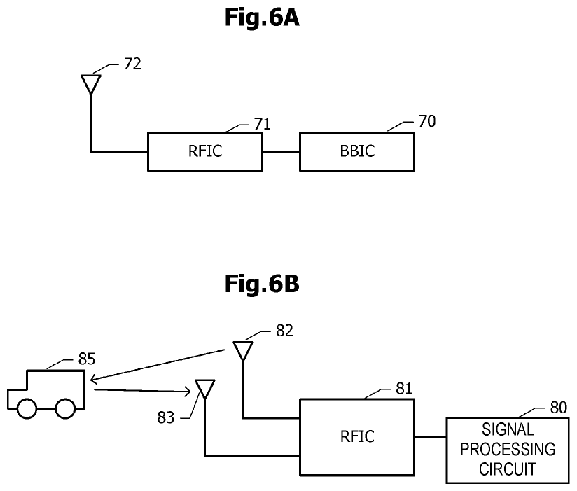

Next, a wireless apparatus according to a fourth embodiment is described with reference to FIG. 6A.

FIG. 6A is a block diagram of the wireless apparatus according to the fourth embodiment. The wireless apparatus according to the fourth embodiment includes an antenna apparatus 72, a high-frequency integrated circuit element (RFIC) 71 as the transmission and reception circuit element, and a baseband integrated circuit element (BBIC) 70. The BBIC 70 supplies at least one of an intermediate-frequency signal, a local signal, and a direct-current power to the RFIC 71 and performs processing for a baseband signal. The RFIC 71 performs processing for a high-frequency signal and supplies the high-frequency signal to the antenna apparatus 72.

The RFIC 71 corresponds to the diplexer 50 and transmission and reception circuit element 51 (FIG. 4B) in the antenna module according to the second embodiment. The antenna apparatus 72 corresponds to the feeding element 11, parasitic element 21, and radiating electrode 23 (FIGS. 4A and 4B) in the antenna module according to the second embodiment. That is, the antenna apparatus 72 has substantially the same configuration as that of the antenna apparatus according to the first embodiment (FIGS. 1A, 1B, and 1C). The BBIC 70 is connected to the signal line 40 in the antenna module according to the second embodiment (FIGS. 4A and 4B) and supplies an intermediate-frequency signal, a local signal, a direct-current power, and the like to the RFIC 71.

Next, great advantages of the fourth embodiment are described. In the fourth embodiment, because substantially the same antenna apparatus according to the first embodiment is used as the antenna apparatus 72, a wide angle and high gain of the antenna apparatus 72 can be achieved, as in the case of the first embodiment.

### Fifth Embodiment

Next, an in-vehicle radar as an example of a wireless apparatus according to a fifth embodiment is described with reference to FIG. 6B.

FIG. 6B is a block diagram of the in-vehicle radar according to the fifth embodiment. The in-vehicle radar according to the fifth embodiment includes a signal processing circuit 80, a high-frequency integrated circuit element (RFIC) 81 as the transmission and reception circuit element, a transmission antenna 82, and a reception antenna 83. The RFIC 81 modulates a carrier wave on the basis of a modulating signal from the signal processing circuit 80 and supplies the modulated high-frequency transmission signal to the transmission antenna 82.

A radio wave emitted from the transmission antenna 82 is reflected from a target 85, such as a vehicle, and the reflected wave is received by the reception antenna 83. The RFIC 81 performs signal processing for a high-frequency transmission signal and a high-frequency reception signal received by the reception antenna 83. In one example, the RFIC 81 may mix the high-frequency transmission signal and the high-frequency reception signal and produce a beat signal.

The signal processing circuit 80 transmits a modulating signal to the RFIC 81. In addition, the signal processing circuit 80 determines at least one of a relative distance to the target 85 and a relative velocity of the target 85 on the basis of a result of the signal processing by the RFIC 81. In one example, the signal processing circuit 80 may determine the relative distance and the relative velocity on the basis of the beat signal produced by the RFIC 81.

As each of the transmission antenna 82 and the reception antenna 83, the antenna apparatus according to the first embodiment (FIGS. 1A, 1B, and 1C) is used. The RFIC 81 may be disposed on or in the first substrate 10, as in the case of the antenna module according to the second embodiment (FIGS. 4A and 4B). In that case, the signal processing circuit 80 may be connected to the signal line 40 (FIGS. 4A and 4B), and transmission and reception of signals between the signal processing circuit 80 and the RFIC 81 may be carried out through the signal line 40 (FIGS. 4A and 4B).

Next, great advantages of the fifth embodiment are described. In the fifth embodiment, because the antenna apparatus according to the first embodiment (FIGS. 1A, 1B, and 1C) is used as each of the transmission antenna 82 and the reception antenna 83, a wide angle and high gain of each of the transmission antenna 82 and the reception antenna 83 can be achieved, as in the case of the first embodiment.

Next, a variation of the fifth embodiment is described. In the fifth embodiment, the single transmission antenna 82 and the single reception antenna 83 are arranged. In the variation, a plurality of transmission antennas 82 and a plurality of reception antennas 83 may be arranged.

The embodiments are illustrative, and the configurations illustrated in different embodiments may be replaced in part or combined. Substantially the same operational advantages provided by substantially the same configurations in a plurality of embodiments are not described in succession for each embodiment. Furthermore, the present disclosure is not limited to the above-described embodiments. For example, it is obvious for those skilled in the art that the above-described embodiments may be changed, modified, combined, and the like variously.

### REFERENCE SIGNS LIST

10 first substrate
11 feeding element
12 feeding line
13 feeding element
14 feeding line
15 ground plane
16, 17 via
20 second substrate
20A, 20B extending portion
21, 22 parasitic element
23 radiating electrode
25 ground plane
26 radiating electrode
31 conducting wire (monopole antenna)
32 dipole antenna
32A, 32B conducting wire
33 dipole antenna
33A, 33B conducting wire
34 conducting wire (loop antenna)
40 signal line
41 land
42 connector
45 ground plane
46 via
50 diplexer
51 transmission and reception circuit element
70 baseband integrated circuit element (BBIC)
71 high-frequency integrated circuit element (RFIC)
72 antenna apparatus
80 signal processing circuit
81 high-frequency integrated circuit element (RFIC)
82 transmission antenna
83 reception antenna
85 target

1. An antenna apparatus comprising:
a feeding terminal on or in a first substrate;
a second substrate that is flexible, that overlies the feeding terminal, and that comprises an extending portion that extends beyond the first substrate;
a parasitic circuit element on or in the second substrate and coupled to the feeding terminal; and
a radiating electrode on the extending portion of the second substrate and connected to the parasitic circuit element.

2. The antenna apparatus according to claim 1, wherein the parasitic circuit element and the radiating electrode are disposed on the same surface of the second substrate.

3. The antenna apparatus according to claim 1, further comprising a ground plane on or in the second substrate at a different layer of the second substrate than the radiating electrode,
wherein the radiating electrode and the ground plane constitute a patch antenna.

4. The antenna apparatus according to claim 2, further comprising a ground plane on or in the second substrate at a different layer of the second substrate than the radiating electrode,
wherein the radiating electrode and the ground plane constitute a patch antenna.

5. An antenna module comprising:
a feeding terminal on or in a first substrate;
a second substrate that is flexible, that overlies the feeding terminal, and that comprises an extending portion that extends beyond the first substrate;
a parasitic circuit element on or in the second substrate and coupled to the feeding terminal;
a radiating electrode on the extending portion of the second substrate and connected to the parasitic circuit element;
a transmission and reception circuit element on or in the first substrate and configured to supply a high-frequency signal to the feeding terminal; and
a signal line on or in the second substrate that is configured to supply an intermediate-frequency signal, a local signal, or a direct-current power to the transmission and reception circuit element, and that extends into the extending portion.

6. A wireless apparatus comprising:
a first antenna comprising:
a feeding terminal on or in a first substrate,
a second substrate that is flexible, that overlies the feeding terminal, and that comprises an extending portion that extends beyond the first substrate,
a parasitic circuit element on or in the second substrate and coupled to the feeding terminal, and
a radiating electrode on or in the extending portion of the second substrate and connected to the parasitic circuit element;
a transmission and reception circuit element on or in the first substrate and configured to supply a high-frequency signal to the feeding terminal;
a signal line on or in the second substrate that is connected to the transmission and reception circuit element, and that extends into the extending portion; and
a baseband integrated circuit configured to supply an intermediate-frequency signal, a local signal, or a direct-current power to the transmission and reception circuit element through the signal line, and configured to perform a baseband signal processing.

7. The wireless apparatus according to claim 6, further comprising a second antenna, wherein:
the first antenna is configured to be a transmission antenna or a reception antenna, and the second antenna is configured to be the other of the transmission antenna or the reception antenna,
the transmission and reception circuit element is configured to supply a high-frequency transmission signal modulated based on a modulating signal to the transmission antenna, and is configured to perform signal processing for the high-frequency transmission signal and a high-frequency reception signal received by the reception antenna, and
the baseband integrated circuit comprises a signal processing circuit configured to transmit the modulating signal to the transmission and reception circuit element, and configured to determine a relative distance to a target or a relative velocity of the target based on a result of the signal processing by the transmission and reception circuit element.

8. The wireless apparatus according to claim 7, wherein the signal processing circuit is connected to the signal line and is configured to supply the modulating signal to the transmission and reception circuit element through the signal line.
